(19) United States
(12) Patent Application Publication
(10) Pub. No.: US 2008/0123282 A1
(43) Pub. Date: May 29, 2008

(54) Expresscard Solid-State Storage Device

(76) Inventors: Huan-Hui Chiang, Pingzhen City (TW); Ching-Chung Hung, Pingzhen City (TW)

Correspondence Address: LIN & ASSOCIATES INTELLECTUAL PROPERTY, INC., P.O. BOX 2339, SARATOGA, CA, 95070-0339, US

(21) Appl. No.: 11/460,251

(22) Filed: Jul. 27, 2006

(51) Int. Cl. H05K 7/00

(52) U.S. Cl. 361/686

(57) ABSTRACT

An ExpressCard solid-state storage device is disclosed herein, which receives an access command coming from a computational device and accesses data accordingly. The ExpressCard solid-state storage device includes a circuit board, an ExpressCard interface, a flash memory, and a controller. When the ExpressCard interface of the storage device is inserted into a corresponding interface of the computational device, the ExpressCard solid-state storage device is electrically connected with the computational device. Then the controller receives a write, read or erase command, which is from the computational device and through the ExpressCard interface, and writes data into the flash memory or reads/erases data from the flash memory accordingly.

### BACKGROUND OF THE INVENTION

1. Field of the Invention

The present invention relates to a storage device, and in particular to an ExpressCard solid-state storage device.

2. The Prior Arts

A conventional computer utilizes a hard disk drive as a data storage device. With the development of hard disk drive technology, the capacity and price thereof is satisfactory. However, when data is accessed, the read/write head of the hard disk drive inevitably physically contacts with the magnetic disk where data is stored. It renders the magnetic disk subject to damage, along with the data stored therein.

In addition, the hard disk drive utilizes a high-speed motor to drive the magnetic disk, which demands high power consumption. This is an especially important issue for portable devices, such as notebook computers, which demands low power consumption.

For storage devices similar to the hard disk drives, flash memory has a most promising future. In fact, Flash memory is considered as a solid-state storage device. Solid-state means that there are no moving parts, that is, everything is electronic instead of mechanical. A flash memory is composed of many transistor memory cells. It uses Fowler-Nordheim tunneling for storage and deletion of data. When data is accessed, electric current flows through the dielectric layer located at the periphery of the floating gate of the transistor memory cells. Accordingly, the transistor memory cells start to fail or mistake after a certain amount of write/erase operations. Though the problem will not occur until a hundred thousand times to a million times of write/erase operations, to minimize the times of write/erase without affecting data access and to further prolong the life span of these storage devices have become the goal of the manufacturers.

Besides the aforementioned problems, conventional hard disk drives are hard to install or remove. Though the problem may be solved with a removable hard disk drive, a case virtually encloses the whole hard disk drive. It causes another problem of heat dissipation. Therefore, the removable storage devices begin to adopt an external design with interface connection to solve the thermal dissipation problem.

External interfaces for computers include a low-speed printer port, a high-speed USB 2.0, and an ExpressCard with a speed as high as 2.5 Gbps. Having a speed almost equivalent to that of SATA, the ExpressCard draws a lot of attention.

The ExpressCard standard is developed by PCMCIA. Though many products supporting ExpressCard were launched in COMPUTEX 2005, they did not hit the retail market until the prevalence of Intel NAPA platform.

Currently, ExpressCard supports two formats, ExpressCard/54 and ExpressCard/34. Compared with a PCMCIA card, its length is about 10 mm shorter, and its thickness is a uniform 5 mm instead of the original three types of thickness specification.

As far as transmission interface is concerned, PCMCIA card transmits data under the PCI framework (earlier 8-bit PCMCIA card even utilizes ISA), and ExpressCard is connected with the system chipset under PCI Express or USB 2.0 framework. Under the USB 2.0 framework, the transmission rate may reach 480 Mbps. The PCI Express link is composed of dual simplex channels. The initial transmission speed is 2.5 Gbps, which is almost equivalent to that of the SATA transmission standard, and this is expected to advance to 4 Gbps in the future.

### SUMMARY OF THE INVENTION

A primary objective of the present invention is to provide an ExpressCard solid-state storage device, which uses an external high-speed ExpressCard interface to access data from a flash memory according to a command from a computational device.

Based on the aforementioned objective, an ExpressCard solid-state storage device in accordance with the present invention receives a command coming from a computational device to access data accordingly. The ExpressCard solid-state storage device comprises a circuit board, an ExpressCard interface, a flash memory, and a controller. When the ExpressCard interface of the storage device is inserted into a corresponding interface of the computational device, the ExpressCard solid-state storage device is electrically connected with the computational device. Then the controller receives a write, read or erase command, which is from the computational device and through the ExpressCard interface, and writes data into the flash memory or reads/erases data from the flash memory accordingly.

### BRIEF DESCRIPTION OF THE DRAWINGS

The present invention will be apparent to those skilled in the art by reading the following detailed description of a preferred embodiment thereof, with reference to the attached drawings.

FIGS. 1A and 1B are schematic views showing an ExpressCard solid-state storage device in accordance with the present invention.

FIG. 2 is a schematic view of a flash memory in accordance with the present invention.

### DETAILED DESCRIPTION OF THE PREFERRED EMBODIMENT

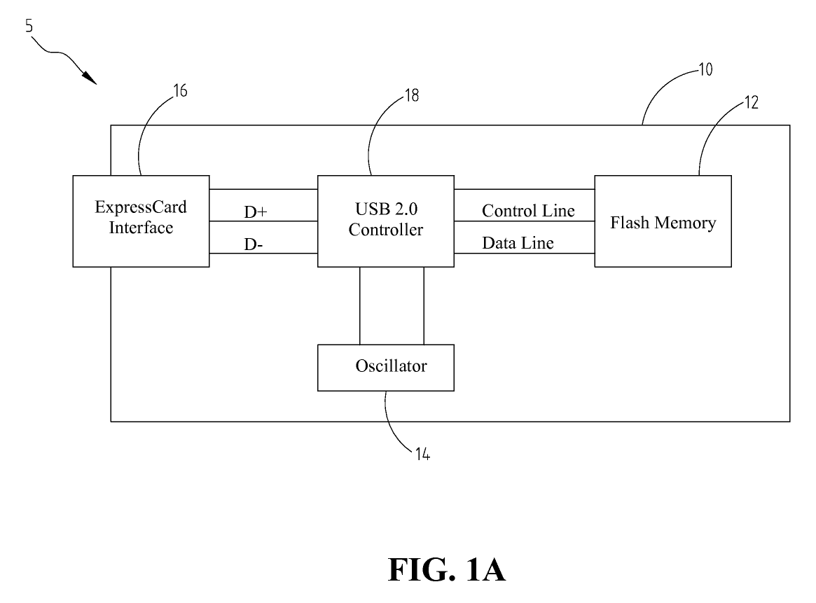

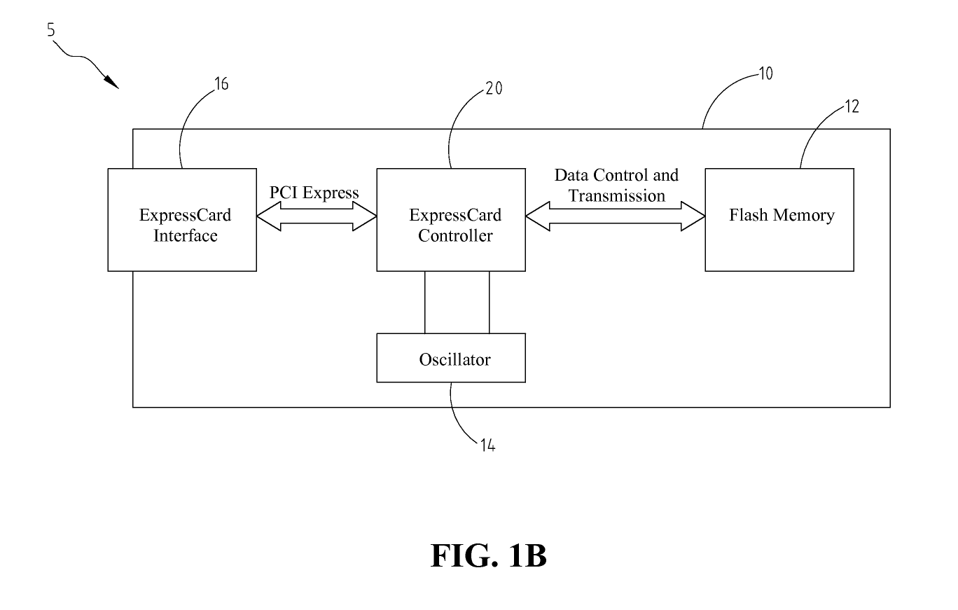

With reference to FIGS. 1A and 1B, which are schematic views of an ExpressCard solid-state storage device in accordance with the present invention, an ExpressCard solid state storage device 5 comprises a circuit board 10, an ExpressCard interface 16, an oscillator 14, a flash memory 12, and a controller 18 or 20, with the latter four installed on the circuit board 10, and is capable of accessing data upon receiving an access command coming from a computational device, such as a notebook computer and a PDA (not shown in the drawings).

As the ExpressCard may adopt PCI Express framework or USB 2.0 framework, embodiments of the present invention under the USB 2.0 framework and under the PCI Express framework are illustrated in FIG. 1A and FIG. 1B, respectively.

As shown in FIG. 1A, when the ExpressCard interface 16 of the ExpressCard solid-state storage device 5 is inserted into a corresponding interface of the computational device, the ExpressCard solid-state storage device 5 is electrically connected with the computational device. The USB 2.0 controller 18 receives a command, which is from the computational device and through the ExpressCard interface 16, and writes data into the flash memory 12 or reads/erases data from the flash memory 12 accordingly. As shown in FIG. 1B, when the USB 2.0 controller 18 is replaced by the ExpressCard controller 20, the framework is the same except that the transmission speed of the PCI Express is increased.

The ExpressCard solid-state storage device 5 may further comprise a USB interface (not shown in the drawings) installed on the circuit board 10. When the USB interface is inserted into a corresponding interface of the computational device, the ExpressCard solid-state storage device 5 is electrically connected with the computational device. Then the controller receives a write, read or erase command, which is from the computational device and through the USB interface, and writes data into the flash memory 12 or reads/erases data from the flash memory 12 accordingly.

The aforementioned flash memory 12 is one of an NAND flash, a Secured Digital (SD) memory card, a Multimedia Card (MMC), a Smart Media (SM) memory card, a Memory Stick, a Compact Flash (CF) memory card, and an XD Picture memory card.

If it is necessary to increase the storage capacity, the ExpressCard solid-state storage device 5 may further comprise a card reader (not shown in the drawings) to read a flash memory card composed of a plurality of flash memories. The access mechanism of the flash memory 12 will be briefly described below.

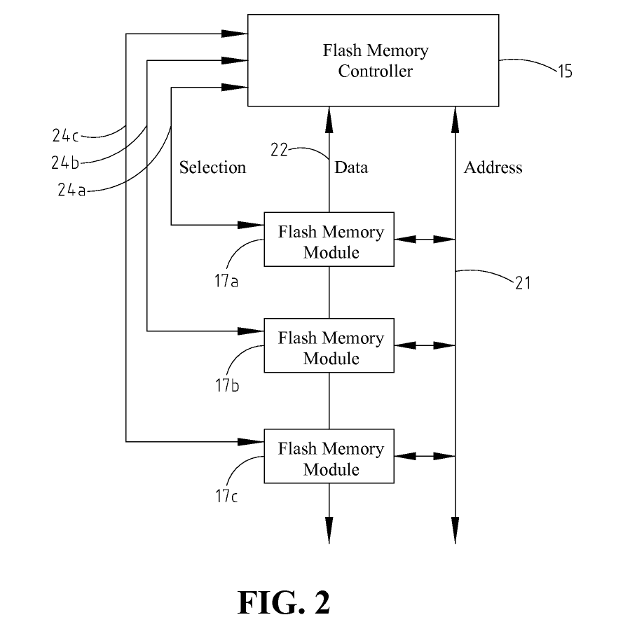

Referring to FIG. 2, it is a schematic view of a flash memory 12 in accordance with the present invention. An address line 21, a data line 22 and selection lines 24a-24c electrically connect corresponding communication channels of flash memory modules 17a-17c and a flash memory controller 15.

First of all, when a command is processed, the location of the data has to be identified according to an allocation table. If the data to be accessed is located at a first address of the flash memory module 17b, the address is selected by the address line 21 and the selection line 24b, and then the data is accessed through the data line 22.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An ExpressCard solid-state storage device for accessing data upon receiving an access command coming from a computational device, comprising:
a circuit board;
an ExpressCard interface installed on said circuit board, which electrically connects said ExpressCard solid-state storage device with said computational device, as it is inserted into a corresponding interface of said computational device;
a flash memory installed on said circuit board for storing data; and
a controller installed on said circuit board, which receives a write, read or erase command coming from said computational device, and writes data into said flash memory or reads/erases data from said flash memory accordingly.

2. The ExpressCard solid-state storage device as claimed in claim 1, further comprising a USB interface installed on said circuit board, which electrically connects said ExpressCard solid-state storage device with said computational device, as it is inserted into a corresponding interface of said computational device; wherein said controller receives a write, read or erase command, which is from said computational device and through said USB interface, and then writes data into said flash memory or reads/erases data from said flash memory accordingly.

3. The ExpressCard solid-state storage device as claimed in claim 1, wherein said flash memory is one of a NAND Flash, a Secured Digital (SD) memory card, a Multimedia Card (MMC), a Smart Media (SM) card, a Memory Stick, a Compact Flash (CF) memory card, and an XD Picture memory card.

4. The ExpressCard solid-state storage device as claimed in claim 1, wherein said controller is one of an ExpressCard controller and a USB controller.

5. The ExpressCard solid-state storage device as claimed in claim 1, wherein the ExpressCard solid-state storage device further comprises a card reader to read a flash memory card composed of a plurality of flash memories in order for increasing storage capacity.
